(19) United States
(12) Patent Application Publication
(10) Pub. No.: US 2024/0274690 A1
(43) Pub. Date: Aug. 15, 2024

(54) SEMICONDUCTOR DEVICE AND METHOD FOR MANUFACTURING SEMICONDUCTOR DEVICE

(71) Applicant: Nuvoton Technology Corporation Japan, Kyoto (JP)

(72) Inventors: Yusuke KANDA, Toyama (JP); Tatsuya YAGI, Toyama (JP); Jun SHIMIZU, Toyama (JP)

(21) Appl. No.: 18/687,233

(22) PCT Filed: Feb. 15, 2023
(86) PCT No.: PCT/JP2023/005189

§ 371 Date: Feb. 27, 2024

Related U.S. Application Data
(60) Provisional application No. 63/320,051, filed on Mar. 15, 2022.

(51) Int. Cl. H01L 29/66; H01L 29/06; H01L 29/20; H01L 29/778

(52) U.S. Cl. CPC H01L 29/66462; H01L 29/0684; H01L 29/7786; H01L 29/2003

(57) ABSTRACT

A semiconductor device includes: a substrate; a buffer layer; an intermediate layer; an electron transport layer; an electron supply layer; a source electrode and a drain electrode; and a gate electrode. The intermediate layer includes a stack resulting from stacking a first intermediate layer and a second intermediate layer. The second intermediate layer is provided above the first intermediate layer. A first position that is 100 nm above a lower surface of the intermediate layer is in the first intermediate layer. A second position that is 100 nm below an upper surface of the intermediate layer is in the second intermediate layer. A value obtained by dividing a density of edge screw mixed dislocations with a Burgers vector of <11-23>/3 at the second position by a density of edge screw mixed dislocations with the Burgers vector of <11-23>/3 at the first position is at most 0.66.

### CROSS-REFERENCE OF RELATED APPLICATIONS

This application is the U.S. National Phase under 35 U.S.C. § 371 of International Patent Application No. PCT/JP2023/005189, filed on Feb. 15, 2023, which in turn claims the benefit of U.S. Provisional Patent Application No. 63/320,051, filed on Mar. 15, 2022, the entire disclosures of which Applications are incorporated by reference herein.

### Technical Field

The present disclosure relates to a semiconductor device and a method for manufacturing the semiconductor device, and in particular to a group III nitride semiconductor device that includes a group III nitride semiconductor.

### Background Art

A group III nitride semiconductor device that includes a group III nitride semiconductor or in particular, gallium nitride (GaN) or aluminum gallium nitride (AlGaN) has a high electrical breakdown voltage since the material has a wide band gap. In the group III nitride semiconductor device, an AlGaN/GaN heterostructure, for instance, can be readily formed.

In the AlGaN/GaN heterostructure, a channel of high-density electrons (hereinafter, referred to as a “two-dimensional electron gas layer (2DEG)”) is formed in the GaN layer at the AlGaN/GaN interface, due to piezo polarization generated from a difference in lattice constant between the materials and spontaneous polarization of AlGaN and GaN. A group III nitride semiconductor in which such a 2DEG channel is utilized has a relatively high electron saturation velocity, a relatively high dielectric strength, and also a relatively high thermal conductivity, and thus is applied to a high-frequency power device.

In order to enhance properties of such a group III nitride semiconductor device, a phenomenon that an electrical property with regard to an output current temporally changes, or stated differently, “current collapse” that is a phenomenon that reproducibility of an output current property deteriorates may be reduced as much as possible.

Patent Literature (PTL) 1 discloses a nitride semiconductor device. The nitride semiconductor device includes a first nitride semiconductor layer, a second nitride semiconductor layer, a third nitride semiconductor layer, and a fourth nitride semiconductor layer. PTL 1 further discloses a structure in which a channel resulting from carriers accumulating in the third nitride semiconductor layer in the vicinity of the interface between the third nitride semiconductor layer and the fourth nitride semiconductor layer is formed, the second nitride semiconductor layer has a greater band gap than that of the third nitride semiconductor layer, and the first nitride semiconductor layer has a band gap greater than or equal to the band gap of the second nitride semiconductor layer and has carbon introduced, which has a higher concentration than that of the second nitride semiconductor layer. Accordingly, current collapse can be reduced by increasing the distance between the third nitride semiconductor layer in which a channel is formed and the first nitride semiconductor layer to which high-concentration carbon is introduced. PTL 1 also discloses that the nitride semiconductor device is a transistor.

### CITATION LIST

### Patent Literature

### PTL 1

International Publication No. WO2012/066701

### SUMMARY OF INVENTION

### Technical Problem

In the nitride semiconductor device stated in PTL 1 above, stacking faults occur in the second nitride semiconductor layer if the thickness of the second nitride semiconductor layer that has less electron traps due to a lower concentration of carbon is simply increased in order to further reduce current collapse. Accordingly, gate leakage in the transistor increases due to stacking faults in the second nitride semiconductor layer, which results in a problem of decrease in yield.

In view of this, the present disclosure provides a semiconductor device and a method for manufacturing a semiconductor device, which can reduce occurrence of stacking faults.

### Solution to Problem

In order to achieve an object as above, a semiconductor device according to an aspect of the present disclosure includes: a substrate; a buffer layer provided above the substrate and consisting essentially of a group III nitride semiconductor; an intermediate layer provided above the buffer layer and consisting essentially of a group III nitride semiconductor having a band gap smaller than a band gap of the group III nitride semiconductor in the buffer layer; an electron transport layer provided above the intermediate layer and consisting essentially of a group III nitride semiconductor having a band gap smaller than the band gap of the group III nitride semiconductor in the intermediate layer; an electron supply layer provided above the electron transport layer and consisting essentially of a group III nitride semiconductor having a band gap greater than the band gap of the group III nitride semiconductor in the electron transport layer; a source electrode and a drain electrode provided above the electron supply layer and spaced apart from each other; and a gate electrode provided above the electron supply layer and spaced apart from each of the source electrode and the drain electrode. The intermediate layer includes a stack resulting from stacking a first intermediate layer and a second intermediate layer. The second intermediate layer is provided above the first intermediate layer. A first position that is 100 nm above a lower surface of the intermediate layer is in the first intermediate layer. A second position that is 100 nm below an upper surface of the intermediate layer is in the second intermediate layer. A value obtained by dividing a density of edge screw mixed dislocations with a Burgers vector of <11-23>/3 at the second position by a density of edge screw mixed dislocations with the Burgers vector of <11-23>/3 at the first position is at most 0.66.

A method for manufacturing a semiconductor device according to an aspect of the present disclosure includes: a first process of forming, above a substrate, a buffer layer consisting essentially of a group III nitride semiconductor; a second process of forming, above the buffer layer, an intermediate layer consisting essentially of a group III nitride semiconductor having a band gap smaller than a band gap of the group III nitride semiconductor in the buffer layer; a third process of forming, above the intermediate layer, an electron transport layer consisting essentially of a group III nitride semiconductor having a band gap smaller than the band gap of the group III nitride semiconductor in the intermediate layer; a fourth process of forming, above the electron transport layer, an electron supply layer consisting essentially of a group III nitride semiconductor having a band gap greater than the band gap of the group III nitride semiconductor in the electron transport layer; a fifth process of forming a source electrode and a drain electrode above the electron supply layer, the source electrode and the drain electrode being spaced apart from each other; and a sixth process of forming a gate electrode above the electron supply layer, the gate electrode being spaced apart from each of the source electrode and the drain electrode. The second process includes: a seventh process of forming a first intermediate layer above the buffer layer; and an eighth process of forming a second intermediate layer above the first intermediate layer. A value obtained by dividing a supply molar amount of a nitrogenous material in the eighth process by a supply molar amount of a group III material in the eighth process is at least 5000 and at most 20000, and a substrate temperature in the eighth process is higher than or equal to a substrate temperature in the seventh process.

### Advantageous Effects of Invention

A semiconductor device and a method for manufacturing a semiconductor device according to the present disclosure can reduce occurrence of stacking faults.

### BRIEF DESCRIPTION OF DRAWINGS

FIG. 1 is a cross sectional view illustrating a configuration of a semiconductor device according to an embodiment.

FIG. 2A is a cross sectional view illustrating a configuration of the semiconductor device while being manufactured.

FIG. 2B is a cross sectional view illustrating a configuration of the semiconductor device while being manufactured.

FIG. 2C is a cross sectional view illustrating a configuration of the semiconductor device while being manufactured.

FIG. 2D is a cross sectional view illustrating a configuration of the semiconductor device while being manufactured.

FIG. 2E is a cross sectional view illustrating a configuration of the semiconductor device while being manufactured.

FIG. 2F is a flowchart illustrating a method for manufacturing the semiconductor device according to the embodiment.

FIG. 2G is a cross sectional view illustrating a configuration of a nitride semiconductor substrate of level 1 according to a comparative example.

FIG. 2H is a cross sectional view illustrating a configuration of a nitride semiconductor substrate of level 2 and level 4 according to comparative examples.

FIG. 3 illustrates a secondary ion mass spectrometry (SIMS) profile of a buffer layer, a first intermediate layer, and a second intermediate layer of level 3.

FIG. 4 is an image showing a stacking fault in the nitride semiconductor substrate of level 2.

FIG. 5 illustrates flowcharts each showing a method for switching a step in which the first intermediate layer is formed to a step in which the second intermediate layer is formed.

FIG. 6 illustrates results showing dependency of a defect detection count measured by a defect inspection machine on the thickness of the first intermediate layer.

FIG. 7 illustrates results showing dependency of gate leakage on the thickness of the second intermediate layer.

### DESCRIPTION OF EMBODIMENTS

The following gives a specific explanation of embodiments, with reference to the drawings.

Note that the embodiments explained below each show a general or specific example. The numerical values, shapes, materials, elements, the arrangement and connection of the elements, steps, and the processing order of the steps, for instance, explained in the following embodiments are mere examples, and thus are not intended to limit the present disclosure. Out of the elements in the following embodiments, elements not recited in any of the independent claims are explained as arbitrary elements.

In addition, the drawings are schematic diagrams and do not necessarily give strict illustration. Accordingly, for example, scales are not necessarily the same in the drawings. In addition, for example, the drawings may illustrate elements with their thicknesses and sizes, for instance, being exaggerated in order to make explanation readily understood. The same numeral is given to substantially the same configuration throughout the drawings, and a redundant explanation is omitted or simplified.

In the Description, a term that indicates a relation between elements such as “parallel” or “perpendicular” and a numerical range are not expressions having only strict meanings, but expressions that mean substantially equivalent ranges, which include a difference of about several percent, for example, are covered.

In the Description, the terms “above/upper” and “below/lower” do not indicate upward (vertically upward) and downward (vertically downward) in the absolute recognition of space, but are rather used as terms defined by a relative positional relation based on the stacking order in a stacked configuration. Furthermore, the terms “above” and “below” are used not only when two elements are spaced apart from each other and another element is present therebetween, but also when two elements are in close contact with each other and touch each other.

In the Description and the drawings, the x axis, the y axis, and the z axis represent three axes of a three-dimensional orthogonal coordinate system. In the embodiments, the z-axis direction is the thickness direction of the substrate. In the Description, the “thickness direction” means the direction of the thickness of the substrate, and is a direction perpendicular to an upper surface of the substrate. The x axis and the y axis are two axes parallel to the upper surface of the substrate. Furthermore, a “plan view” refers to a view in a direction perpendicular to the upper surface of the substrate.

In the Description, ordinal numerals such as “first” and “second” do not mean the number of or the order of elements, unless otherwise stated in particular. Thus, the ordinal numerals are used to avoid confusion of and distinguish between elements of the same type.

### EMBODIMENT

### Configuration

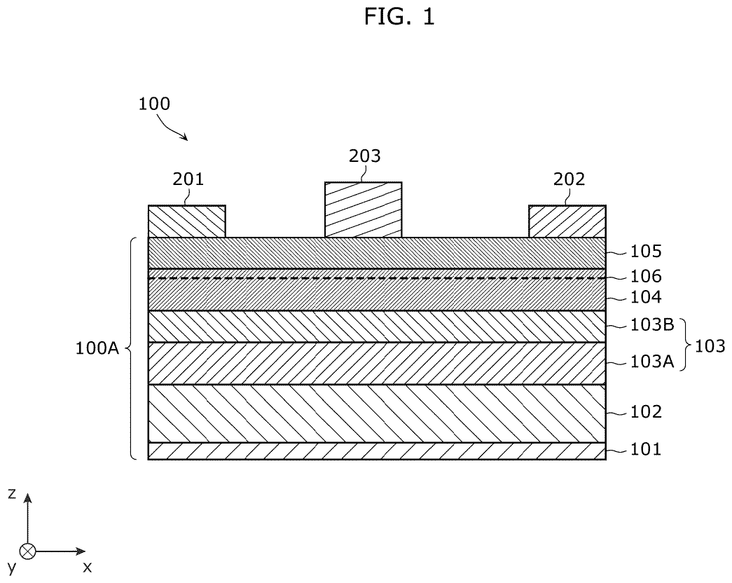

First, semiconductor device 100 according to an embodiment is to be explained with reference to FIG. 1. FIG. 1 is a cross sectional view illustrating a configuration of semiconductor device 100 according to the embodiment.

In the present embodiment, the case where semiconductor device 100 is a high electron mobility transistor (HEMT) is to be explained. Furthermore, semiconductor device 100 is a nitride semiconductor device.

As illustrated in FIG. 1, semiconductor device 100 includes nitride semiconductor substrate 100A, gate electrode 203, source electrode 201, and drain electrode 202. Nitride semiconductor substrate 100A includes substrate 101, buffer layer 102, intermediate layer 103 that includes first intermediate layer 103A and second intermediate layer 103B, electron transport layer 104, electron supply layer 105, and two-dimensional electron gas layer (2DEG) 106.

In the present embodiment, substrate 101 is a base substrate above which, for example, buffer layer 102, intermediate layer 103, electron transport layer 104, and electron supply layer 105 can be formed. Note that an upper surface (a surface on the z-axis positive side) of substrate 101 is a surface above which the layers stated above such as buffer layer 102 are formed. Substrate 101 consists essentially of Si. More specifically, substrate 101 is a Si (111) single-crystal substrate (that is, a Si single-crystal substrate having a (111) surface). Substrate 101 is not limited to such a Si (111) single-crystal substrate, but may be a substrate consisting essentially of sapphire, SiC, GaN, or AlN, for instance. Note that the thickness of the Si (111) single-crystal substrate that is substrate 101 may be at least 675 μm and at most 1200 μm.

Buffer layer 102 is provided above substrate 101. In the present embodiment, buffer layer 102 is, for example, a layer consisting essentially of a group III nitride semiconductor (that is, a group III nitride semiconductor layer), which has a thickness of 2 μm. Note that the thickness of buffer layer 102 is not limited to the above. More specifically, buffer layer 102 is a group III nitride semiconductor layer having a structure of a plurality of stacked layers that include AlN and AlGaN. Buffer layer 102 may include a single layer or a plurality of layers each consisting essentially of a group III nitride semiconductor such as GaN, AlGaN, AlN, InGaN, or AlInGaN. Buffer layer 102 may include a superlattice structure in which a plurality of Al_{1-α}Ga_{α}N (0≤α≤0.8) layers are stacked. Note that buffer layer 102 may be configured of a stack of at least 20 and at most 100 pairs each including AlN and AlGaN layers.

Buffer layer 102 includes a region in which a carbon concentration is 2.0E+19 atoms·cm⁻³, for example. Note that the carbon concentration of buffer layer 102 may be at least 1.0E+19 atoms·cm⁻³ and at most 3.0E+20 atoms·cm⁻³.

Note that the upper surface (a surface on the z-axis positive side) of buffer layer 102 may terminate with SiHₓ (x=0, 1, 2, or 3). More specifically, dangling bonds at the upper surface of buffer layer 102 may terminate with SiHₓ (x=0, 1, 2, or 3). For example, dangling bonds at the upper surface of buffer layer 102 terminate as stated above by supplying SiH₄ gas to the upper surface of buffer layer 102. SiH₄ is adsorbed at dislocations at the upper surface of buffer layer 102 so that properties of buffer layer 102 are modified. Accordingly, mixed dislocations can be reduced. Note that a mixed dislocation means a mixed edge-screw dislocation that is a mixture of an edge dislocation and a screw dislocation. A stacking fault is known to occur from a screw dislocation as a starting point, and the occurrence of a stacking fault can be reduced by reducing such mixed edge-screw dislocations.

Intermediate layer 103 is a group III nitride semiconductor layer provided above buffer layer 102. More specifically, intermediate layer 103 is a group III nitride semiconductor layer having a band gap smaller than that of buffer layer 102 and greater than that of electron transport layer 104. Intermediate layer 103 includes a stack of first intermediate layer 103A and second intermediate layer 103B. More specifically, intermediate layer 103 includes first intermediate layer 103A and second intermediate layer 103B. First intermediate layer 103A is provided above buffer layer 102, and second intermediate layer 103B is provided above first intermediate layer 103A. First intermediate layer 103A and second intermediate layer 103B are each a group III nitride semiconductor layer having a band gap smaller than that of buffer layer 102 and greater than that of electron transport layer 104.

In the present embodiment, the thickness of intermediate layer 103 is 1075 nm, for example. Intermediate layer 103 (that is, each of first intermediate layer 103A and second intermediate layer 103B) includes AlGaN having an average Al composition percentage of 5%. Note that a definition of an average Al composition percentage is as follows. An average Al composition percentage of a layer is shown by Expression 1 when a chemical formula of a group III nitride included in the layer is expressed by AlₐIn_{b}Ga_{c}N (a+b+c=1, a≥0, b≥0, and c≥0).

$$( a / ( a + b + c ) ) \times 100 \% \qquad ( Expression 1 )$$

Next, the thickness of second intermediate layer 103B is 400 nm, whereas the thickness of first intermediate layer 103A is 675 nm.

Note that the thickness of intermediate layer 103 may be at least 1000 nm and at most 2000 nm, and may further be at least 1000 nm and at most 1395 nm.

The thickness of second intermediate layer 103B may be at least 100 nm and at most 400 nm, but is not limited thereto. The thickness of first intermediate layer 103A may be at least 600 nm and at most 1000 nm, but is not limited thereto.

Note that the average Al composition percentage of intermediate layer 103 may be at least 1% and at most 10%. Moreover, the average Al composition percentage may satisfy a relation of buffer layer 102>first intermediate layer 103A≥second intermediate layer 103B. In this manner, the higher position a layer is provided in, the lower average Al composition percentage the layer may have. The average Al composition percentage of first intermediate layer 103A may be at least 5% and at most 10%. Furthermore, a difference between the average Al composition percentage of second intermediate layer 103B and the average Al composition percentage of first intermediate layer 103A may be at most 5%. In this manner, distortion in intermediate layer 103 can be reduced, and the occurrence of stacking faults can be reduced. In intermediate layer 103, the average Al composition percentage may be changed continuously, rather than stepwise. Furthermore, intermediate layer 103 (first intermediate layer 103A and second intermediate layer 103B) may include In.

Note that the upper surface (a surface on the z-axis positive side) of first intermediate layer 103A may terminate with SiH_{y} (y=0, 1, 2, or 3). More specifically, dangling bonds at the upper surface of first intermediate layer 103A may terminate with SiH_{y} (y=0, 1, 2, or 3). For example, dangling bonds at the upper surface of first intermediate layer 103A terminate as stated above by supplying SiH₄ gas to the upper surface of first intermediate layer 103A. SiH₄ is adsorbed at dislocations at the upper surface of first intermediate layer 103A, so that properties of first intermediate layer 103A are modified. Accordingly, mixed dislocations can be reduced, and the occurrence of stacking faults can be reduced.

The carbon concentration of first intermediate layer 103A is 2.6E+16 atoms·cm⁻³, for example. Note that the carbon concentration of first intermediate layer 103A may be at least 2E+16 atoms·cm⁻³ and at most 7E+16 atoms·cm⁻³.

The carbon concentration of second intermediate layer 103B is 6.5E+15 atoms·cm⁻³, for example. Note that the carbon concentration of second intermediate layer 103B may be at least 1.0E+15 atoms·cm⁻³ and at most 2E+16 atoms·cm⁻³ that is a value normally referred to as a detection limit.

The carbon concentration of second intermediate layer 103B may be lower than the carbon concentration of first intermediate layer 103A, and the carbon concentration of first intermediate layer 103A may be lower than the carbon concentration of buffer layer 102.

Intermediate layer 103 is explained as a layer that includes two layers that are first intermediate layer 103A and second intermediate layer 103B in the present embodiment, but may include a plurality of layers more than two layers, or a thin AlN layer may be provided in intermediate layer 103 in order to control warping of nitride semiconductor substrate 100A.

Electron transport layer 104 is provided above intermediate layer 103. More specifically, electron transport layer 104 is provided above second intermediate layer 103B of intermediate layer 103. In the present embodiment, electron transport layer 104 is, for example, a GaN layer having a thickness of 150 nm, but the thickness of electron transport layer 104 is not limited thereto. Note that rather than being limited to GaN, electron transport layer 104 may include a group III nitride semiconductor such as InGaN, AlGaN, or AlInGaN, and may include n-type impurities. Electron transport layer 104 is a group III nitride semiconductor layer having a band gap smaller than that of the intermediate layer.

Electron supply layer 105 is a group III nitride semiconductor layer provided above electron transport layer 104. Electron supply layer 105 is a group III nitride semiconductor layer having a band gap smaller than that of electron transport layer 104. In the present embodiment, electron supply layer 105 has a thickness of 20 nm, for example, but the thickness thereof is not limited thereto. Electron supply layer 105 includes AlGaN having an average Al composition percentage of 25%. High-concentration 2DEG 106 is generated in electron transport layer 104 at the hetero interface between electron supply layer 105 and electron transport layer 104. Nitride semiconductor substrate 100A according to the present embodiment includes a channel that is such 2DEG 106.

Note that the average Al composition percentage of electron supply layer 105 may be at least 20% and at most 100%. Electron supply layer 105 may include an In-contained group III nitride semiconductor such as AlInGaN or InAlN, rather than being limited to AlGaN. Electron supply layer 105 may include n-type impurities.

Gate electrode 203 is provided above electron supply layer 105. Gate electrode 203 is spaced apart from each of source electrode 201 and drain electrode 202. In the present embodiment, gate electrode 203 is a multi-layer electrode film having a stack structure in which a Ni film and an Al film are stacked in this order, but is not limited thereto. Gate electrode 203 makes Schottky connection with electron supply layer 105 by being in contact with electron supply layer 105. Note that connection between gate electrode 203 and electron supply layer 105 is not limited to Schottky connection, and an insulating film or a group III nitride semiconductor may be provided between gate electrode 203 and electron supply layer 105.

Source electrode 201 and drain electrode 202 are provided above electron supply layer 105 and across gate electrode 203 from each other. Stated differently, source electrode 201 and drain electrode 202 are spaced apart from each other. In the present embodiment, source electrode 201 and drain electrode 202 are each a multi-layer electrode film having a stack structure in which a Ti film and an Al film are stacked in this order, but are not limited thereto. Source electrode 201 and drain electrode 202 each electrically make ohmic connection with 2DEG 106.

### Method for Manufacturing Semiconductor Device

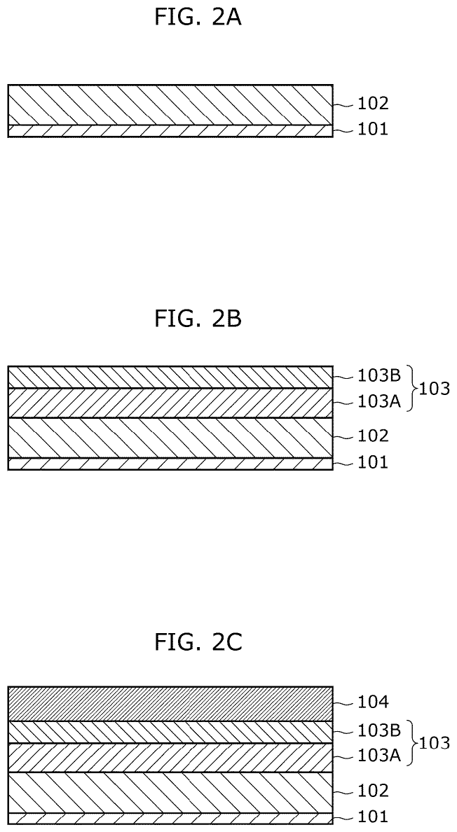

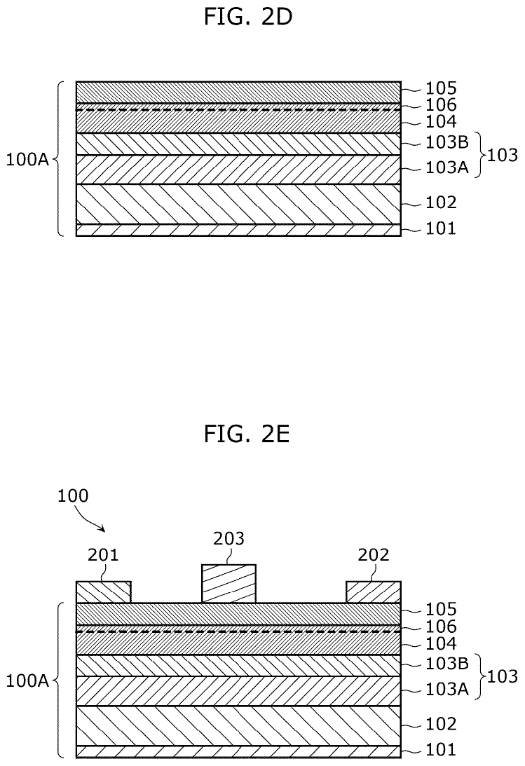

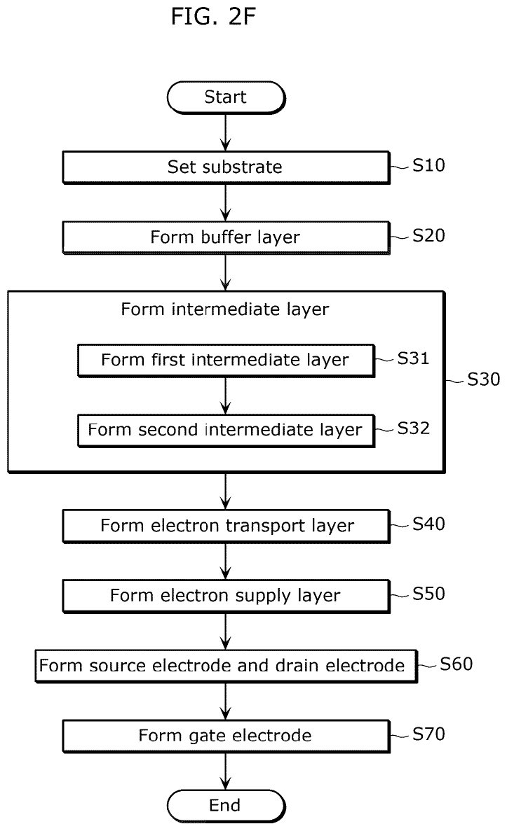

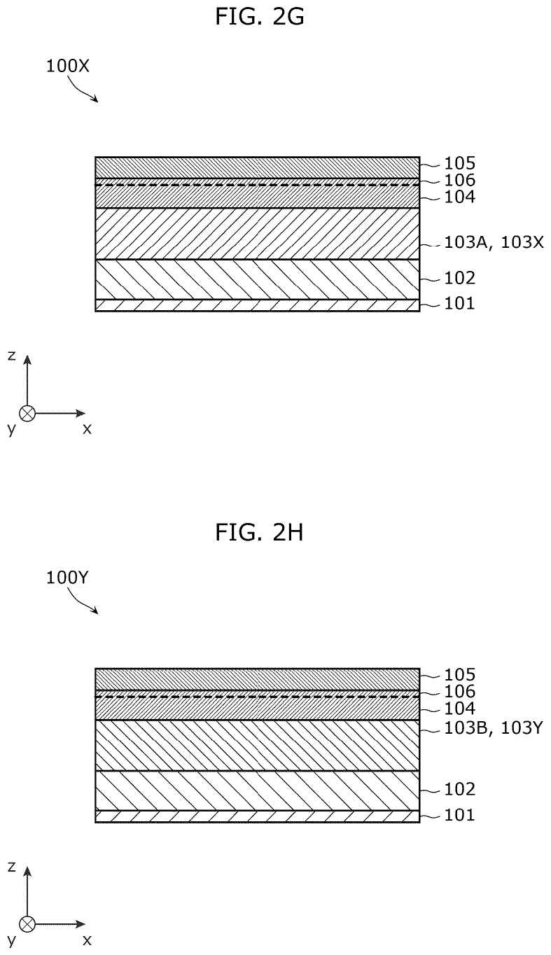

The following gives an explanation of a method for manufacturing semiconductor device 100 in the embodiment, with reference to FIG. 2A to FIG. 2F.

FIG. 2A to FIG. 2E are cross sectional views each illustrating a configuration of semiconductor device 100 while being manufactured. FIG. 2F is a flowchart illustrating a method for manufacturing semiconductor device 100 according to the embodiment.

Nitride semiconductor substrate 100A is formed by forming group III nitride semiconductor layers such as buffer layer 102, intermediate layer 103, electron transport layer 104, and electron supply layer 105, above substrate 101 consisting essentially of Si by using metal organic chemical vapor deposition (MOCVD). Here, a semiconductor crystal growth device for forming nitride semiconductor substrate 100A is used.

First, substrate 101 consisting essentially of Si is placed in the semiconductor crystal growth device (S10).

Next, as illustrated in FIG. 2A, buffer layer 102 is formed above substrate 101 consisting essentially of Si (S20). Buffer layer 102 is a group III nitride semiconductor layer that has, for example, a thickness of 2 μm and a structure of a plurality of stacked layers that include AlN and AlGaN. Buffer layer 102 is a group III nitride semiconductor layer resulting from sequential epitaxial growth in the +c-plane direction (the <0001>direction) in the semiconductor crystal growth device. Buffer layer 102 includes a layer having a carbon concentration of at least 1.0E+19 atoms·cm⁻³.

A temperature condition and a pressure condition as below are applied as growth conditions for buffer layer 102. For example, a condition that the substrate temperature is at least 600° C. and at most 1200° C. is applied as the temperature condition. Note that a condition that a growth pressure is a lower pressure (that is, a pressure lower than or equal to the atmospheric pressure) may be applied as the pressure condition, and the growth pressure may be specifically at most 50 KPa.

Such step S20 corresponds to a first process.

Next, as illustrated in FIG. 2B, intermediate layer 103 is formed above buffer layer 102 (S30). Intermediate layer 103 has a thickness of 1075 nm, for example. Intermediate layer 103 is obtained by epitaxial growth of AlGaN having an average Al composition percentage of 5%.

Such step S30 corresponds to a second process. In step S30 (the second process), steps S31 and S32 as below are performed. Specifically, in step S30, first intermediate layer 103A is formed above buffer layer 102 (S31) and furthermore, second intermediate layer 103B is formed above first intermediate layer 103A (S32). Such step S31 corresponds to a seventh process, and step S32 corresponds to an eighth process.

Since steps S31 and S32 are performed, intermediate layer 103 includes two layers having different carbon concentrations (first intermediate layer 103A and second intermediate layer 103B), for example. First intermediate layer 103A has a thickness of 675 nm and has a carbon concentration of 2.6E+16 atoms·cm⁻³. Second intermediate layer 103B has a thickness of 400 nm and has a carbon concentration of 6.5E+15 atoms·cm⁻³.

In step S30, carrier gases are N₂ and H₂. In step S30, the growth pressure is 30 kPa, for example. Note that the lower pressure condition may be applied as the pressure condition in step S30, and the growth pressure may be at most 80 KPa.

For example, the substrate temperature in step S31 in which first intermediate layer 103A is formed is 1114° C., and the substrate temperature in step S32 in which second intermediate layer 103B is formed is 1144° C. The substrate temperature in step S32 in which second intermediate layer 103B is formed is higher than or equal to the substrate temperature in step S31 in which first intermediate layer 103A is formed. Note that the substrate temperature in step S32 in which second intermediate layer 103B is formed may be at least 1100° C. and at most 1250° C. In this manner, epitaxial growth in a lateral direction (that is, the direction parallel to the xy plane) can be facilitated, and thus mixed dislocations in second intermediate layer 103B can be decreased and the occurrence of stacking faults can be reduced.

The gas flow rate of NH₃ in steps S31 and S32 is 50 slm, for example. Note that NH₃ corresponds to a nitrogenous material in each of steps S31 and S32. In step S31 in which first intermediate layer 103A is formed, the flow rate of trimethyl gallium (TMG) is 81.6 sccm, and the flow rate of trimethyl aluminum (TMA) is 18.7 sccm. In step S32 in which second intermediate layer 103B is formed, the flow rate of TMG is 40.8 sccm, and the flow rate of TMA is 9.6 sccm.

Note that TMG and TMA correspond to group III materials in each of steps S31 and S32.

Specifically, ((a supply molar amount of nitrogenous material)/(a supply molar amount of the group III materials)) (hereinafter, referred to as V/III ratio) in step S31 in which first intermediate layer 103A is formed is 4497, and the V/III ratio for second intermediate layer 103B is 8984. Note that the V/III ratio in step S32 in which second intermediate layer 103B is formed is at least 5000 and at most 20000.

Note that in step S30 (the second process), a process (a ninth process) of stopping supply of a group III material gas may be performed between steps S31 and S32. In the present embodiment, a method in which, for example, the ninth process of stopping supply of the group III materials is performed for one minute is used as a method for switching from step S31 in which first intermediate layer 103A is formed to step S32 in which second intermediate layer 103B is formed. Thus, supply of the group III materials is interrupted for one minute between steps S31 and S32.

Next, as illustrated in FIG. 2C, electron transport layer 104 is formed above intermediate layer 103 (or more specifically, second intermediate layer 103B) (S40). Electron transport layer 104 has a thickness of 150 nm, for example. Electron transport layer 104 is obtained by epitaxial growth of GaN.

The temperature condition and the pressure condition as below are applied as the growth conditions for electron transport layer 104. As the temperature condition, for example, a condition that the substrate temperature is at least 900° C. and at most 1200° C. may be applied and furthermore, a condition that the substrate temperature is at least 1000° C. and at most 1150° C. may be applied. As the pressure condition, a condition that the growth pressure is the normal pressure or the lower pressure may be applied. Since GaN to which impurities are intentionally not added is used for electron transport layer 104, current collapse caused by such impurities can be reduced. Note that after intermediate layer 103 is formed, electron transport layer 104 may be continuously formed without stopping supply of the group III material gas. The substrate temperature may be the same in step S40 in which electron transport layer 104 is formed and step S32 in which second intermediate layer 103B is formed. Such step S40 corresponds to a third process.

Next, as illustrated in FIG. 2D, electron supply layer 105 is formed above electron transport layer 104 (S50). Electron supply layer 105 has, for example, a thickness of 20 nm and includes AlGaN having an average Al composition percentage of 25%.

Since electron supply layer 105 is formed above electron transport layer 104, 2DEG 106 is formed at an interface between electron transport layer 104 and electron supply layer 105, due to influence of spontaneous polarization and piezo polarization caused by a difference in lattice constant. Thus, 2DEG 106 is generated in electron transport layer 104 at the interface between electron transport layer 104 and electron supply layer 105.

The temperature condition and the pressure condition as below are applied as the growth conditions for electron supply layer 105. As the temperature condition, for example, a condition that the substrate temperature is at least 900° C. and at most 1200° C. may be applied and furthermore, a condition that the substrate temperature is at least 1000° C. and at most 1150° C. may be applied. As the pressure condition, a condition that the growth pressure is the lower pressure may be applied, and the growth pressure may specifically be at most 80 KPa. Of course, the average Al composition percentage and the thickness of electron supply layer 105 and conditions for forming electron supply layer 105 can be changed as necessary. Such step S50 corresponds to a fourth process.

In this manner, nitride semiconductor substrate 100A is formed.

Next, as illustrated in FIG. 2E, source electrode 201 and drain electrode 202 are formed above electron supply layer 105, being spaced apart from each other (S60). The following gives a more specific explanation. First, nitride semiconductor substrate 100A is preliminarily washed with hydrochloric acid, and Ti and Al are deposited in this order above electron supply layer 105 by sputtering. After that, a film in which Ti and Al are stacked are patterned by sequentially applying lithography and dry etching, so that source electrode 201 and drain electrode 202 each having a predetermined shape are formed above electron supply layer 105. Note that source electrode 201 and drain electrode 202 each having a predetermined shape may be formed by sequentially applying lithography and lift-off. Next, source electrode 201 and drain electrode 202 are electrically connected to 2DEG 106 by performing heat treatment under a nitrogen atmosphere. Such step S60 corresponds to a fifth process.

Next, gate electrode 203 is formed above electron supply layer 105, being spaced apart from each of source electrode 201 and drain electrode 202 (S70). The following gives a more specific explanation. TIN and Al are deposited in this order above electron supply layer 105 by sputtering. After that, a film in which TIN and Al are stacked is patterned by sequentially applying lithography and dry etching, so that gate electrode 203 is formed above electron supply layer 105. Note that gate electrode 203 having a predetermined shape may be formed by sequentially applying lithography and lift-off. Such step S70 corresponds to a sixth process.

Semiconductor device 100 having the structure illustrated in FIG. 1 is obtained through the series of processes explained above.

### Reasons for Arriving at the Present Disclosure and Results of Experiments

In the following, reasons for arriving at the present disclosure are to be explained based on the results of experiments.

Table 1 shows, for each experimental level according to the embodiment, results of experiments based on growth conditions for intermediate layer 103 and average Al composition percentages and carbon concentrations of intermediate layer 103. Table 1 shows, for each experimental level according to comparative examples, results of experiments based on growth conditions for an intermediate layer, and average Al composition percentages and carbon concentrations of the intermediate layer.

TABLE 1

| | Level 1 | | Level 2 | | Level 3 | | Level 4 | | Level 5 | |
|---|---|---|---|---|---|---|---|---|---|---|
| | First | Second | First | Second | First | Second | First | Second | First | Second |
| | Inter- | Inter- | Inter- | Inter- | Inter- | Inter- | Inter- | Inter- | Inter- | Inter- |
| | mediate | mediate | mediate | mediate | mediate | mediate | mediate | mediate | mediate | mediate |
| | layer | layer | layer | layer | layer | layer | layer | layer | layer | layer |
| Substrate | 1114 | 1144 | 1114 | 1144 | 1114 | 1144 | 1114 | 1144 | 1114 | 1144 |
| temperature [° C.] | | | | | | | | | | |
| Growth pressure | 30 | 30 | 30 | 30 | 30 | 30 | 30 | 30 | 30 | 30 |
| [kPa] | | | | | | | | | | |
| Carrier gas | H₂, N₂ | H₂, N₂ | H₂, N₂ | H₂, N₂ | H₂, N₂ | H₂, N₂ | H₂, N₂ | H₂, N₂ | H₂, N₂ | H₂, N₂ |
| NH [symbol] flow rate | 50 | 50 | 50 | 50 | 50 | 50 | 50 | 50 | 50 | 50 |
| [slm] | | | | | | | | | | |
| TMG flow rate | 81.6 | 40.8 | 81.6 | 40.8 | 81.6 | 40.8 | 81.6 | 37.1 | 81.6 | 40,8 |
| [sccm] | | | | | | | | | | |
| TMA flow rate | 18.7 | 9.6 | 18.7 | 9.6 | 18.7 | 9.6 | 18.7 | 31.3 | 13.7 | 9.6 |
| [sccm] | | | | | | | | | | |
| V/III ratio | 4497 | 8984 | 4497 | 8984 | 4497 | 8984 | 4497 | 8984 | 4497 | 8984 |
| Ninth process of | Performed | | Performed | | Performed | | Performed | | Not performed | |
| stopping supply of | | | | | | | | | | |
| group III material | | | | | | | | | | |
| gas | | | | | | | | | | |
| Thickness [nm] | 1075 | 0 | 0 | 1075 | 500 | 575 | 0 | 1075 | 500 | 575 |
| Average Al | 5 | — | — | 5 | 5 | 5 | — | 10 | 5 | 5 |
| composition | | | | | | | | | | |
| percentage [%] | | | | | | | | | | |
| Carbon | 2.6E−16 | — | — | 6.5E+15 | 2.6E+16 | 6.5E+15 | — | 6.5E+15 | 2.6E+16 | 6.5E+15 |
| concentration | | | | | | | | | | |
| [atmos/cm³] | | | | | | | | | | |

[symbol]

indicates data missing or illegible when filed

Here, nitride semiconductor substrates of level 1 to level 5 are produced, and level 1 to level 5 are used as experimental levels. Level 1, level 2, and level 4 are experimental levels according to the comparative examples, and level 3 and level 5 are levels according to the present embodiment. Nitride semiconductor substrates of level 1, level 2, and level 4 are to be explained with reference to FIG. 2G and FIG. 2H.

FIG. 2G is a cross sectional view illustrating a configuration of nitride semiconductor substrate 100X of level 1 according to a comparative example. FIG. 2H is a cross sectional view illustrating a configuration of nitride semiconductor substrate 100Y of level 2 and level 4 according to comparative examples.

As illustrated in FIG. 2G, nitride semiconductor substrate 100X of level 1 has the same configuration as that of nitride semiconductor substrate 100A according to the present embodiment, except that intermediate layer 103X is included instead of intermediate layer 103. Intermediate layer 103X includes only first intermediate layer 103A and does not include second intermediate layer 103B.

As illustrated in FIG. 2H, nitride semiconductor substrate 100Y of level 2 and level 4 has the same configuration as that of nitride semiconductor substrate 100A according to the present embodiment, except that intermediate layer 103Y is included instead of intermediate layer 103. Intermediate layer 103Y includes only second intermediate layer 103B and does not include first intermediate layer 103A.

Also at level 1, level 2, and level 4 that are experimental levels according to the comparative examples, a manufacturing method the same as the manufacturing method of level 3 according to the present embodiment is used, unless stated in particular.

Note that the configuration of nitride semiconductor substrate 100A of level 3 and level 5 that are the levels according to the present embodiment is as illustrated in FIG. 1.

The nitride semiconductor substrates of level 1 to level 5 are to be explained below.

As shown in Table 1, a total thickness of first intermediate layer 103A and second intermediate layer 103B was set to 1075 nm. Next, the carbon concentration of first intermediate layer 103A is 2.6E+16 atoms·cm⁻³, and the carbon concentration of second intermediate layer 103B is 6.5E+15 atoms·cm⁻³. Accordingly, the carbon concentration of second intermediate layer 103B is lower than the carbon concentration of first intermediate layer 103A.

As stated above, intermediate layer 103X is formed of only first intermediate layer 103A at level 1, and intermediate layer 103Y is formed of only second intermediate layer 103B at level 2. Thus, intermediate layer 103X and intermediate layer 103Y are single layers at level 1 and level 2, respectively.

At level 3, intermediate layer 103 includes first intermediate layer 103A that is the same condition as that of level 1, and second intermediate layer 103B that is the same condition as that of level 2. Thus, intermediate layer 103 is a stack of layers having different properties. Note that the thickness of first intermediate layer 103A of level 3 is 500 nm, and the thickness of second intermediate layer 103B of level 3 is 575 nm.

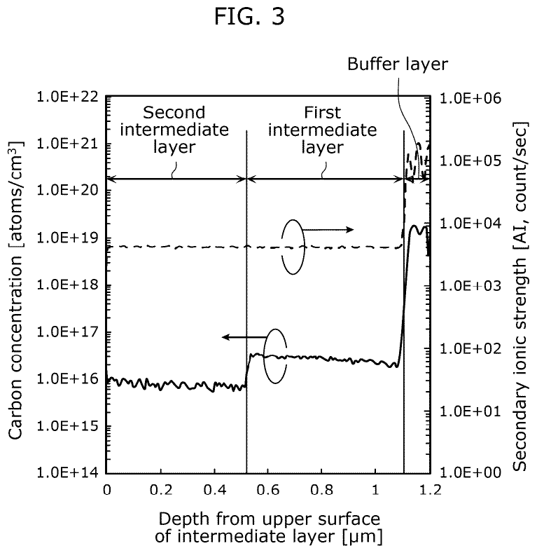

FIG. 3 illustrates a secondary ion mass spectrometry (SIMS) profile of buffer layer 102, first intermediate layer 103A, and second intermediate layer 103B of level 3. More specifically, FIG. 3 shows results of analysis of carbon concentrations and Al secondary ion concentrations of buffer layer 102, first intermediate layer 103A, and second intermediate layer 103B of level 3. Note that the horizontal axis in FIG. 3 shows a depth from the upper surface of intermediate layer 103 (more specifically, second intermediate layer 103B). As can be seen from FIG. 3, the carbon concentration of second intermediate layer 103B is lower than the carbon concentration of first intermediate layer 103A. The average Al composition percentage satisfies a relation of buffer layer 102>first intermediate layer 103A≥second intermediate layer 103B.

Note that the carbon concentrations at level 1, level 2, level 4, and level 5, which are shown in Table 1, were evaluated using the analysis illustrated in FIG. 3.

At level 4, intermediate layer 103Y is formed of only second intermediate layer 103B, which is the same as at level 2. Level 4 is the same as level 2, except that an average Al composition percentage of intermediate layer 103Y is 10%.

First intermediate layer 103A and second intermediate layer 103B of level 5 have the same structures as those of first intermediate layer 103A and second intermediate layer 103B of level 3. Note that at level 5, the ninth process of stopping supply of the group III material gas is not performed between step S31 in which first intermediate layer 103A is formed and step S32 in which second intermediate layer 103B is formed.

Defect detection counts of the nitride semiconductor substrates produced at level 1 to level 3 (stated differently, nitride semiconductor substrate 100X of level 1, nitride semiconductor substrate 100Y of level 2, and nitride semiconductor substrate 100A of level 3) were measured using a defect inspection machine. INSPECTRA 3000SR-III200 manufactured by Toray Engineering Co., Ltd. was used as the defect inspection machine. Here, stacking faults and defects other than stacking faults are detected as defects.

Furthermore, mixed dislocation densities of the nitride semiconductor substrates produced at level 1 to level 3 were measured using a transmission electron microscope (TEM). Dislocations with a Burgers vector of <11-23>/3, which were obtained using the transmission electron microscope (TEM), are edge screw mixed dislocations that are mixtures of edge dislocations and screw dislocations. Here, densities of edge screw mixed dislocations with a Burgers vector of <11-23>/3 were measured for level 1 to level 3. Furthermore, an index as below was used to quantify an effect of reducing the mixed dislocation density of an intermediate layer. First, the mixed dislocation density at a second position 100 nm below an upper surface of each of the intermediate layers (more specifically, intermediate layers 103, 103X, and 103Y) is measured, and the mixed dislocation density at a first position 100 nm above a lower surface of each of the intermediate layers (more specifically, intermediate layers 103, 103X, and 103Y) is measured. When the mixed dislocation density at the first position is denoted by B, and the mixed dislocation density at the second position is denoted by A, a mixed dislocation density ratio (A/B) was evaluated as an index, in order to quantify an effect of reducing the mixed dislocation density.

If the mixed dislocation density ratio is small, or more specifically, is sufficiently smaller than 1, this indicates that the mixed dislocation density at the second position that is a higher position in an intermediate layer is lower than the mixed dislocation density at the first position that is a position lower in the intermediate layer, and thus it can be said that a great effect of reducing the mixed dislocation density of the intermediate layer is achieved. Furthermore, if the mixed dislocation density ratio is sufficiently smaller than 1, this indicates that the mixed dislocation density is lower as a position is higher in the intermediate layer.

Note that at level 3 that is a level according to the present embodiment, the first position 100 nm above the lower surface of intermediate layer 103 is in first intermediate layer 103A, whereas the second position 100 nm below the upper surface of intermediate layer 103 is in second intermediate layer 103B.

Table 2 shows results of experiments in defect detection counts, whether stacking faults have occurred, and mixed dislocation densities at level 1 to level 3.

TABLE 2

| | | | Average | | | | A: Mixed | B: Mixed | |
|---|---|---|---|---|---|---|---|---|---|
| | | | Al | | | | dislocation | dislocation | |
| | Thick- | Thick- | com- | Defect | | | density at second | density at first | |
| | ness | ness | position | detection | | | position | position | |
| | of | of | percentage | count by | | | 100 nm | 100 nm | Mixed |
| | first | second | of | defect | | Whether | below upper | above lower | dis- |
| | inter- | inter- | second | inspection | Measured | stacking | surface of | surface of | location |
| | mediate | mediate | inter- | machine | position | faults | intermediate | intermediate | density |
| | layer | layer | mediate | [Total | of | have | layer | layer | ratio |
| | [nm] | [nm] | layer | number] | wa [symbol] 2er | occurred | [10 [symbol] cm⁻²] | [10 [symbol] cm⁻²] | (A/B) |
| Level 1 | 1075 | 0 | — | 178 | Center | No | 6.0 | 9.2 | 0.66 |
| | | | | | Outer | No | 12.2 | 27.3 | 0.45 |
| | | | | | perimeter | | | | |
| Level 2 | 0 | 1075 | 5 | 91160 | Center | Yes | 19.7 | 20.0 | 0.98 |
| | | | | | Outer | Yes | 27.3 | 38.0 | 0.72 |
| | | | | | perimeter | | | | |
| Level 3 | 500 | 575 | 5 | 552 | Center | No | 24.3 | 44.0 | 0.55 |
| | | | | | Outer | Yes | 27.3 | 26.0 | 1.05 |
| | | | | | perimeter | | | | |

[symbol]

indicates data missing or illegible when filed

More specifically, Table 2 shows counts of defects (defect detection count) detected by the defect inspection machine from the nitride semiconductor substrates of level 1 to level 3. Table 2 also shows, for a center and an outer perimeter of each of the nitride semiconductor substrates of level 1 to level 3, whether stacking faults have occurred, A denoting a mixed dislocation density at the second position, B denoting a mixed dislocation density at the first position, and a mixed dislocation density ratio (A/B). Note that when such a nitride semiconductor substrate is used for an HEMT, a center region of the nitride semiconductor substrate is more important than an outer perimeter region thereof, and thus experimental results for the center are more important.

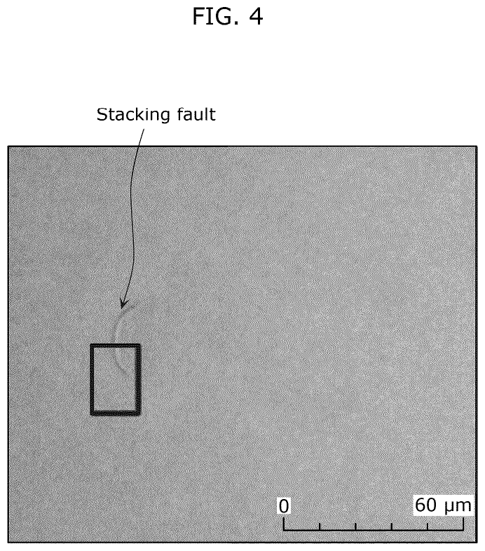

First, two levels that are level 1 and level 2, or stated differently, the levels at which intermediate layers 103X and 103Y are each a single layer are to be compared. The defect detection count (91160) at level 2 has increased 512 times more than the defect detection count (178) at level 1. FIG. 4 is an image showing a stacking fault at level 2 detected by the defect inspection machine. More specifically, FIG. 4 is an image showing a stacking fault in nitride semiconductor substrate 100Y of level 2. The stacking fault shown in FIG. 4 is a stacking fault that has occurred in one of the layers included in nitride semiconductor substrate 100Y. Note that a semilunar defect detected by the defect inspection machine using ultraviolet (UV) rays is referred to as a stacking fault herein. A stacking fault in a nitride semiconductor substrate can be a leakage path when an HEMT is produced using the nitride semiconductor substrate, and thus stacking faults may be reduced. As stated above, the defect inspection machine detects, as defects, stacking faults and defects other than the stacking faults. The defect detection counts shown in Table 2 each include both of a defect detection count of stacking faults and a defect detection count of defects other than the stacking faults. Here, a background level of a defect detection count of the defects other than the stacking faults is approximately 300. Accordingly, it can be determined that stacking faults have occurred at a level at which the defect detection count greatly exceeds such a value of approximately 300. As shown in Table 2, it can be determined that stacking faults have not occurred at level 1 at which the defect detection count is 178, whereas stacking faults have occurred at level 2 at which the defect detection count is 91160. Furthermore, it was checked that stacking faults have not occurred in both of the center and the outer perimeter of nitride semiconductor substrate 100X of level 1, and that stacking faults have occurred in both of the center and the outer perimeter of nitride semiconductor substrate 100Y of level 2.

A stacking fault is known to occur from a screw dislocation as a starting point. Thus, a mixed dislocation density may be reduced in order to reduce stacking faults. A comparison of the mixed dislocation density ratio (A/B) in the center between level 1 and level 2 shows that the mixed dislocation density ratio is lower at level 1. More specifically, at level 1, the mixed dislocation density ratio is sufficiently lower than 1, that is, 0.66, so that it can be said that a great effect of reducing the mixed dislocation density of intermediate layer 103X is achieved, as stated above. Accordingly, at level 1, the mixed dislocation density at a higher position (the second position) in intermediate layer 103X can be sufficiently reduced, and this it can be considered that stacking faults in the center are reduced.

The above shows that a mixed dislocation density ratio may be at most 0.66 from the results of experiments in Table 2, in order to reduce stacking faults to a degree higher than or equal to level 1, or stated differently, in order to eliminate stacking faults.

Furthermore, level 3 that is a level according to the present embodiment is to be examined. At level 3 at which intermediate layer 103 is a stack of layers having different properties, a defect detection count was decreased to 1/100 the defect detection count at level 2 at which intermediate layer 103Y is a single layer. Furthermore, since the defect detection count at level 3 was 552 and exceeded the value of approximately 300, it was determined that stacking faults have occurred. However, as shown in Table 2, it was made clear that at level 3, stacking faults did not occur in the center that is a more important region.

The mixed dislocation density ratio in the center is 0.66 at level 1 and 0.55 at level 3. Accordingly, at level 3 that is a level according to the present embodiment, intermediate layer 103 includes first intermediate layer 103A and second intermediate layer 103B, and thus a mixed dislocation density ratio in the center is at most 0.66, or more specifically, 0.55. It can be said that at level 3 that is a level according to the present embodiment, the mixed dislocation density ratio in the center is lower than that at level 1 that is a level according to a comparative example, so that a greater effect of reducing the mixed dislocation density of intermediate layer 103 is achieved than that achieved at level 1. This shows that a stack of layers having different properties at level 3 is better as an intermediate layer than a single layer at level 1. Accordingly, at level 3, the mixed dislocation density at a higher position (the second position) in intermediate layer 103 can be sufficiently reduced, and this it is considered that stacking faults in the center are reduced.

Furthermore, stacking faults being less at level 3 at which intermediate layer 103 is a stack of layers having different properties are considered to be because the number of mixed dislocations at the interface between first intermediate layer 103A and second intermediate layer 103B was reduced for the following two reasons.

The first reason is as follows. In step S32 in which second intermediate layer 103B is formed, a V/III ratio is at least 5000 and at most 20000 and is specifically 8984, indicating that the ratio is high. As a result, a nitrogen surface of second intermediate layer 103B is stably formed and growth of second intermediate layer 103B in the lateral direction is facilitated by reducing migration of Ga, which can be raised as the first reason.

The second reason is as follows. The substrate temperature in step S32 in which second intermediate layer 103B is formed is higher than or equal to the substrate temperature in step S31 in which first intermediate layer 103A is formed, and is specifically a high temperature of 1144° C. As a result of this, in step S32, etching using H₂ that is a carrier gas is facilitated, and growth of second intermediate layer 103B in the lateral direction is facilitated, which can be raised as the second reason.

From the above, the V/III ratio in step S32 in which second intermediate layer 103B is formed may be at least 5000 and at most 20000. The substrate temperature in step S32 in which second intermediate layer 103B is formed may be higher than or equal to the substrate temperature in step S31 in which first intermediate layer 103A is formed. In step S32, the substrate temperature with which growth in the lateral direction is facilitated may be at least 1100° C. and at most 1250° C. Stated differently, when the substrate temperature in step S32 in which second intermediate layer 103B is formed is at least 1100° C. and at most 1250° C., growth of second intermediate layer 103B is more facilitated, and the occurrence of stacking faults is reduced.

Next, level 1 and level 3 are to be compared. Here, a carbon concentration is focused on.

As stated in Background Art above, current collapse may be reduced as much as possible. A factor for generating such current collapse can be electrons being trapped. Carbon in intermediate layer 103 is an electron trap source, and electrons are readily trapped as the carbon concentration in intermediate layer 103 is higher. Thus, a carbon concentration in intermediate layer 103 needs to be sufficiently reduced in order to reduce current collapse.

The carbon concentration in intermediate layer 103X (first intermediate layer 103A) of level 1 is 2.6E+16 atoms·cm⁻³. The carbon concentrations in first intermediate layer 103A and second intermediate layer 103B of level 3 are 2.6E+16 atoms·cm⁻³ and 6.5E+15 atoms·cm⁻³, respectively. At level 3, the TMG flow rate and the TMA flow rate when second intermediate layer 103B is formed are approximately half the TMG flow rate and the TMA flow rate when first intermediate layer 103A is formed. Accordingly, the carbon concentration in second intermediate layer 103B can be sufficiently reduced as compared with first intermediate layer 103A. Accordingly, as compared with intermediate layer 103X of level 1, second intermediate layer 103B included in intermediate layer 103 of level 3 has a carbon concentration sufficiently reduced, and thus current collapse can be sufficiently reduced at level 3 as compared with level 1.

Next, defect detection counts of the manufactured nitride semiconductor substrates of level 2 and level 4 are measured using the defect inspection machine. Table 3 shows experimental results of defect detection counts at level 2 and level 4.

TABLE 3

| | | | | Defect |
|---|---|---|---|---|
| | | | | detection |
| | | | Al composition | count by |
| | Thickness of | Thickness of | percentage of | defect |
| | first | second | second | inspection |
| | intermediate | intermediate | intermediate | machine |
| | layer | layer | layer | [Total |
| | [nm] | [nm] | [%] | number] |
| Level 2 | 0 | 1075 | 5 | 91160 |
| Level 4 | 0 | 1075 | 10 | 3352 |

As is clear from the experimental results in Table 3, the defect detection count has decreased at level 4, as compared with level 2. This shows that the average Al composition percentage of second intermediate layer 103B may be higher in order to eliminate stacking faults. This is because the smaller a difference in average Al composition percentage between buffer layer 102 (the average Al composition percentage: at least 20% and at most 100%) and intermediate layer 103Y (second intermediate layer 103B), the smaller distortion is caused in intermediate layer 103Y, and thus the occurrence of stacking faults is considered to have been reduced. A similar phenomenon is assumed to occur also at level 3 that is a level according to the present embodiment, and thus also at level 3, an average Al composition percentage may be buffer layer 102>first intermediate layer 103A>second intermediate layer 103B.

Thus, also in the present embodiment, the average Al composition percentage of first intermediate layer 103A may be higher than or equal to the average Al composition percentage of second intermediate layer 103B, and the average Al composition percentage of buffer layer 102 may be higher than the average Al composition percentage of first intermediate layer 103A.

Accordingly, distortions caused in first intermediate layer 103A and second intermediate layer 103B decrease. Thus, semiconductor device 100 that can further reduce occurrence of stacking faults can be implemented.

In the present embodiment, the average Al composition percentage of first intermediate layer 103A may be at least 5% and at most 10%.

Accordingly, when the average Al composition percentage of buffer layer 102 is at least 20% and at most 100%, distortion caused in first intermediate layer 103A decreases. Thus, semiconductor device 100 that can further reduce occurrence of stacking faults can be implemented.

In the present embodiment, a difference between the average Al composition percentage of second intermediate layer 103B and the average Al composition percentage of first intermediate layer 103A may be at most 5%.

Accordingly, distortion caused in second intermediate layer 103B is further decreased. Accordingly, semiconductor device 100 that can further reduce occurrence of stacking faults can be implemented.

Next, defect detection counts of the manufactured nitride semiconductor substrates of level 3 and level 5 are measured using the defect inspection machine. Table 4 shows experimental results of defect detection counts at level 3 and level 5.

TABLE 4

| | | | Al composition | | Defect detection |
|---|---|---|---|---|---|
| | Thickness of | Thickness of | percentage of | | count by defect |
| | first | second | second | Ninth process of | inspection |
| | intermediate | intermediate | intermediate | stopping supply of | machine |
| | layer | layer | layer | group III material | [Total |
| | [nm] | [nm] | [%] | gas | number] |
| Level 3 | 500 | 575 | 5 | Performed | 552 |
| | | | | Interrupt duration | |
| | | | | 1 min | |
| Level 5 | 500 | 575 | 5 | Not performed | 769 |

Level 3 and level 5 are both levels according to the present embodiment. Nitride semiconductor substrate 100A of level 3 is manufactured by performing the ninth process, and nitride semiconductor substrate 100A of level 5 is manufactured without performing the ninth process.

From the experimental results in Table 4, the defect detection count at level 3 is less than that at level 5, or stated differently, the occurrence of stacking faults is less at level 3 than at level 5. Thus, the results show that in order to reduce stacking faults, the ninth process of stopping supply of the group III material gas may be performed between step S31 in which first intermediate layer 103A is formed and step S32 in which second intermediate layer 103B is formed.

This is explained as below. If supply of a group III material is interrupted, growth at a high temperature of at least 1100° C. is interrupted, and thus the surface of first intermediate layer 103A is etched using H₂ that is a carrier gas to roughen the surface of intermediate layer 103A. Accordingly, the orientation of dislocations is changed when second intermediate layer 103B grows and the number of mixed dislocations is decreased by mutual interference of dislocations, so that the defect detection count is considered to have decreased at level 3.

Thus, the second process may include the ninth process of stopping supply of the group III material gas, between the seventh process and the eighth process.

Accordingly, a method for manufacturing semiconductor device 100 that can reduce the occurrence of stacking faults is achieved.

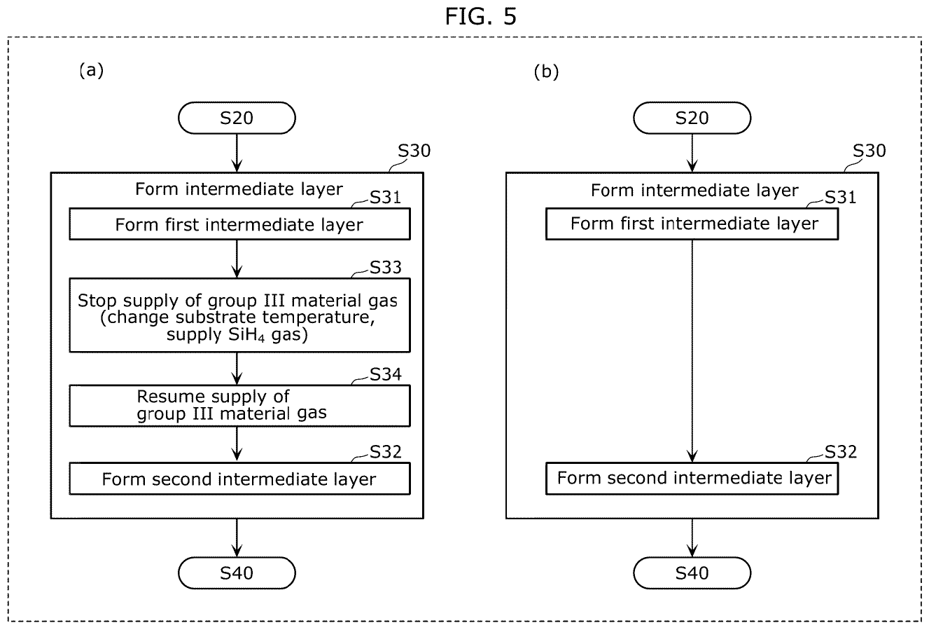

Furthermore, the ninth process is to be explained with reference to FIG. 5.

FIG. 5 illustrates flowcharts each showing a method for switching step S31 in which first intermediate layer 103A is formed to step S32 in which second intermediate layer 103B is formed. More specifically, (a) of FIG. 5 shows a flowchart according to level 3 at which the ninth process is performed, whereas (b) of FIG. 5 shows a flowchart according to level 5 at which the ninth process is not performed.

As shown in (a) of FIG. 5, steps S10, S20, and S31 are performed in the method for manufacturing nitride semiconductor substrate 100A of level 3. Furthermore, the ninth process of stopping supply of the group III material gas (S33) is performed. Thus, in this case, supply of the group III material gas is interrupted. After that, supply of the group III material gas is resumed (S34), and second intermediate layer 103B is formed (S32). Note that when the substrate temperature is changed in step S31 and step S32, such a change may be made while supply of the group III material gas is stopped (that is, during the ninth process (S33)). The duration of the ninth process (S33), that is, the duration for which supply of the group III material gas is interrupted is at least one minute and at most five minutes. Since the duration is at least one minute, the surface of first intermediate layer 103A can be sufficiently roughened. Since the duration is at most five minutes, productivity can be increased. In ninth process (S33), SiH₄ may be supplied. Since SiH₄ is supplied while supply of a group III material is interrupted (the ninth process (S33)), the upper surface of first intermediate layer 103A terminates with SiH_{y}. Accordingly, SiH₄ is adsorbed at dislocations at the upper surface of first intermediate layer 103A, so that properties of first intermediate layer 103A are modified. Thus, it can be expected that mixed dislocations are reduced, and the occurrence of stacking faults is reduced.

Accordingly, in the present embodiment, the duration of the ninth process may be at least one minute and at most five minutes.

The surface of first intermediate layer 103A can be sufficiently roughened, and also productivity can be increased.

In the present embodiment, a SiH₄ gas is supplied in the ninth process.

Accordingly, SiH₄ is adsorbed at dislocations at the upper surface of first intermediate layer 103A, so that properties of first intermediate layer 103A are modified. Thus, mixed dislocations can be reduced, and the occurrence of stacking faults can be reduced.

As shown in (b) of FIG. 5, at level 5, nitride semiconductor substrate 100A is manufactured without performing the ninth process.

Semiconductor device 100 and a method for manufacturing semiconductor device 100 according to the present embodiment are summarized as follows.

Semiconductor device 100 according to the present embodiment includes: substrate 101; buffer layer 102 provided above substrate 101 and consisting essentially of a group III nitride semiconductor; intermediate layer 103 provided above buffer layer 102 and consisting essentially of a group III nitride semiconductor having a band gap smaller than a band gap of the group III nitride semiconductor in buffer layer 102; electron transport layer 104 provided above intermediate layer 103 and consisting essentially of a group III nitride semiconductor having a band gap smaller than the band gap of the group III nitride semiconductor in intermediate layer 103; electron supply layer 105 provided above electron transport layer 104 and consisting essentially of a group III nitride semiconductor having a band gap greater than the band gap of the group III nitride semiconductor in electron transport layer 104; source electrode 201 and drain electrode 202 provided above electron supply layer 105 and spaced apart from each other; and gate electrode 203 provided above electron supply layer 105 and spaced apart from each of source electrode 201 and drain electrode 202. Intermediate layer 103 includes a stack resulting from stacking first intermediate layer 103A and second intermediate layer 103B. Second intermediate layer 103B is provided above first intermediate layer 103A. A first position that is 100 nm above a lower surface of intermediate layer 103 is in first intermediate layer 103A. A second position that is 100 nm below an upper surface of intermediate layer 103 is in second intermediate layer 103B. A value (that is, A/B which is a mixed dislocation density ratio) obtained by dividing a density (A) of edge screw mixed dislocations with a Burgers vector of <11-23>/3 at the second position by a density (B) of edge screw mixed dislocations with the Burgers vector of <11-23>/3 at the first position is at most 0.66.

Accordingly, as shown by the nitride semiconductor substrate of level 3, intermediate layer 103 includes first intermediate layer 103A and second intermediate layer 103B, and thus the mixed dislocation density ratio (A/B) is at most 0.66, or more specifically, 0.55. In the present embodiment (for example, at level 3), the mixed dislocation density ratio (A/B) in the center is lower than that at level 1 that is a level according to a comparative example, so that it can be said that a greater effect of reducing the mixed dislocation density of intermediate layer 103 is achieved than that achieved at level 1. Accordingly, in the present embodiment, the mixed dislocation density at a higher position (the second position) in intermediate layer 103 is sufficiently reduced. Thus, semiconductor device 100 that can reduce the number of stacking faults based on the mixed dislocation density at the second position and thus can reduce the occurrence of stacking faults is implemented.

A method for manufacturing semiconductor device 100 according to the present embodiment includes: a first process of forming, above substrate 101, buffer layer 102 consisting essentially of a group III nitride semiconductor; a second process of forming, above buffer layer 102, intermediate layer 103 consisting essentially of a group III nitride semiconductor having a band gap smaller than a band gap of the group III nitride semiconductor in buffer layer 102; a third process of forming, above intermediate layer 103, electron transport layer 104 consisting essentially of a group III nitride semiconductor having a band gap smaller than the band gap of the group III nitride semiconductor in intermediate layer 103; a fourth process of forming, above electron transport layer 104, electron supply layer 105 consisting essentially of a group III nitride semiconductor having a band gap greater than the band gap of the group III nitride semiconductor in electron transport layer 104; a fifth process of forming source electrode 201 and drain electrode 202 above electron supply layer 105, source electrode 201 and drain electrode 202 being spaced apart from each other; and a sixth process of forming gate electrode 203 above electron supply layer 105, gate electrode 203 being spaced apart from each of source electrode 201 and drain electrode 202. The second process includes: a seventh process of forming first intermediate layer 103A above buffer layer 102; and an eighth process of forming second intermediate layer 103B above first intermediate layer 103A. A value (a V/III ratio) obtained by dividing a supply molar amount of a nitrogenous material in the eighth process by a supply molar amount of a group III material in the eighth process is at least 5000 and at most 20000, and a substrate temperature in the eighth process is higher than or equal to a substrate temperature in the seventh process.

Accordingly, as shown by the nitride semiconductor substrate of level 3, intermediate layer 103 includes first intermediate layer 103A and second intermediate layer 103B, and thus the mixed dislocation density ratio (A/B) is at most 0.66, or more specifically, 0.55. In the present embodiment (for example, at level 3), the mixed dislocation density ratio (A/B) in the center is lower than that at level 1 that is a level according to a comparative example, so that it can be said that a greater effect of reducing the mixed dislocation density of intermediate layer 103 is achieved than that achieved at level 1. Accordingly, in the present embodiment, the mixed dislocation density at a higher position (the second position) in intermediate layer 103 is sufficiently reduced. Thus, a method for manufacturing semiconductor device 100 that can reduce the number of stacking faults based on the mixed dislocation density at the second position and thus can reduce the occurrence of stacking faults is implemented.

Furthermore, since the V/III ratio in step S32 (the eighth process) in which second intermediate layer 103B is formed is at least 5000 and at most 20000, the nitrogenous surface of second intermediate layer 103B is stably formed, and migration of Ga is reduced and growth of second intermediate layer 103B in the lateral direction is facilitated. Accordingly, the method for manufacturing semiconductor device 100 according to the present embodiment can further reduce the occurrence of stacking faults.

Yet furthermore, since the substrate temperature in step S32 in which second intermediate layer 103B is formed is higher than or equal to the substrate temperature in step S31 (the seventh process) in which first intermediate layer 103A is formed, etching using H₂ that is a carrier gas is facilitated, and growth of second intermediate layer 103B in the lateral direction is facilitated. Accordingly, the method for manufacturing semiconductor device 100 according to the present embodiment can further reduce the occurrence of stacking faults.

The thickness of intermediate layer 103 according to the present embodiment is further examined in the following.

As illustrated in FIG. 3, the carbon concentration of buffer layer 102 is extremely higher than the carbon concentrations of first intermediate layer 103A and second intermediate layer 103B. From the aspect of electrons being trapped in carbon in buffer layer 102, the distance between electron transport layer 104 and buffer layer 102 may be at least 1000 nm. Accordingly, the thickness of intermediate layer 103 was made 1075 nm and 1395 nm, and dependency on the thicknesses of first intermediate layer 103A and second intermediate layer 103B when intermediate layer 103 has such properties.

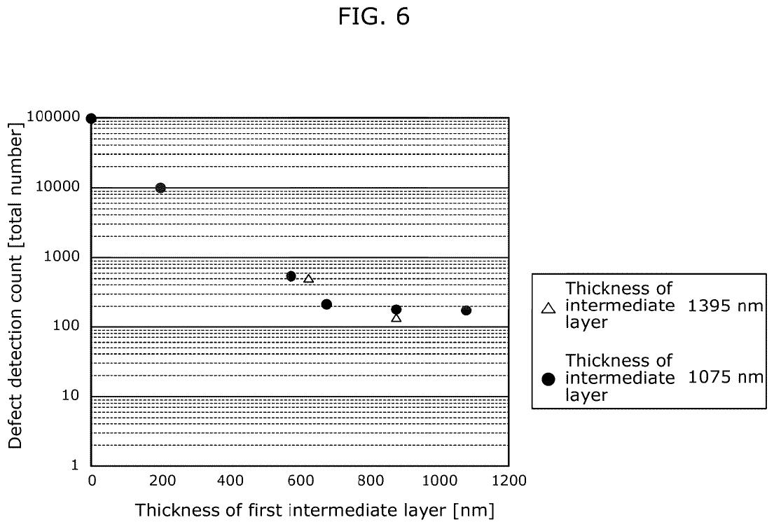

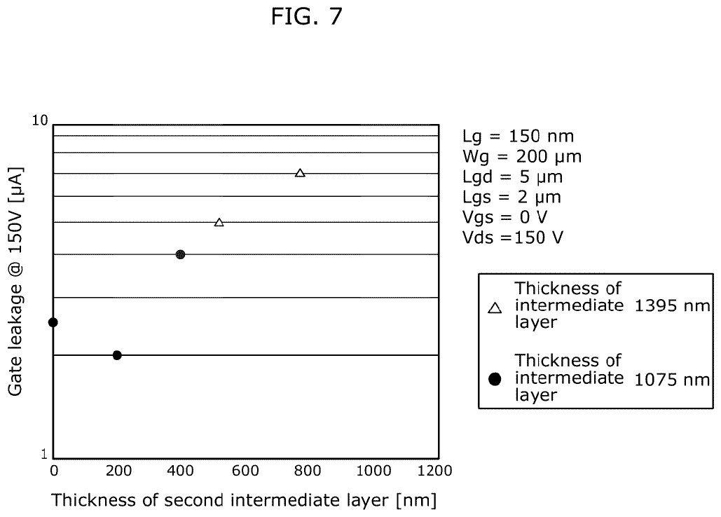

FIG. 6 illustrates dependency of the defect detection count measured by the defect inspection machine on the thickness of first intermediate layer 103A. As can be seen from FIG. 6, irrespective of the thickness of intermediate layer 103, if first intermediate layer 103A is thicker, the defect detection count is lower. A decrease in the defect detection count is saturated when the thickness of first intermediate layer 103A is 600 nm or more, and thus the thickness of first intermediate layer 103A may be at least 600 nm.

FIG. 7 illustrates results showing dependency of gate leakage on the thickness of second intermediate layer 103B. More specifically, FIG. 7 shows results of measuring gate leakage in semiconductor device 100 in a state in which the thickness of second intermediate layer 103B is changed. As illustrated in FIG. 7, conditions for measuring gate leakage are as follows. Lg that denotes the length of gate electrode 203 (the length in the x-axis direction) is 150 nm, Wg that denotes the width of gate electrode 203 (the width in the y-axis direction) is 200 μm, Lgd that denotes the distance between gate electrode 203 and drain electrode 202 (the distance in the x-axis direction) is 5 μm, and Lgs that denotes the distance (the distance in the x-axis direction) between gate electrode 203 and source electrode 201 is 2 μm. Vgs that is a voltage between gate electrode 203 and source electrode 201 is 0V, and Vds that denotes a voltage between drain electrode 202 and source electrode 201 is 150V. As can be seen from FIG. 7, when the thickness of second intermediate layer 103B is greater, gate leakage decreases. A decrease in gate leakage is saturated when the thickness of second intermediate layer 103B is 400 nm or less, and thus the thickness of second intermediate layer 103B may be at most 400 nm.

Thus, in the present embodiment, the thickness of intermediate layer 103 may be at least 1000 nm and at most 1395 nm.

Accordingly, the distance between electron transport layer 104 and buffer layer 102 having a high carbon concentration can be sufficiently increased, and electrons being trapped in carbon in buffer layer 102 is reduced, or stated differently, current collapse is reduced.

In the present embodiment, the thickness of first intermediate layer 103A may be at least 600 nm.

Accordingly, semiconductor device 100 that can decrease the defect detection count, and thus can further reduce the occurrence of stacking faults is implemented.

In the present embodiment, the thickness of second intermediate layer 103B may be at most 400 nm.

Accordingly, gate leakage in semiconductor device 100 can be decreased.

### Other Embodiments

The above has explained the semiconductor devices according to one or more aspects, based on embodiments, but the present disclosure is not limited to the embodiments, for instance. The present disclosure also encompasses embodiments as a result of adding, to the embodiments, various modifications that may be conceived by those skilled in the art, and embodiments obtained by combining elements and functions in the embodiments without departing from the scope of the present disclosure.

Various changes, replacement, addition, and omission, for instance, can be made to the above embodiments within the scope of the claims and the equivalents thereof.

### Industrial Applicability

A semiconductor device according to the present disclosure is useful in a communication device and an inverter that are required to operate at high speed and a power switching element for use in a power supply circuit, for instance.

1. A semiconductor device comprising:
a substrate;
a buffer layer provided above the substrate and consisting essentially of a group III nitride semiconductor;
an intermediate layer provided above the buffer layer and consisting essentially of a group III nitride semiconductor having a band gap smaller than a band gap of the group III nitride semiconductor in the buffer layer;
an electron transport layer provided above the intermediate layer and consisting essentially of a group III nitride semiconductor having a band gap smaller than the band gap of the group III nitride semiconductor in the intermediate layer;
an electron supply layer provided above the electron transport layer and consisting essentially of a group III nitride semiconductor having a band gap greater than the band gap of the group III nitride semiconductor in the electron transport layer;
a source electrode and a drain electrode provided above the electron supply layer and spaced apart from each other; and
a gate electrode provided above the electron supply layer and spaced apart from each of the source electrode and the drain electrode,
wherein the intermediate layer includes a stack resulting from stacking a first intermediate layer and a second intermediate layer,
the second intermediate layer is provided above the first intermediate layer,
a first position that is 100 nm above a lower surface of the intermediate layer is in the first intermediate layer,
a second position that is 100 nm below an upper surface of the intermediate layer is in the second intermediate layer, and
a value obtained by dividing a density of edge screw mixed dislocations with a Burgers vector of <11-23>/3 at the second position by a density of edge screw mixed dislocations with the Burgers vector of <11-23>/3 at the first position is at most 0.66.

2. The semiconductor device according to claim 1,
wherein a thickness of the intermediate layer is at least 1000 nm and at most 1395 nm.

3. The semiconductor device according to claim 2,
wherein a thickness of the first intermediate layer is at least 600 nm.

4. The semiconductor device according to claim 3,
wherein a thickness of the second intermediate layer is at most 400 nm.

5. The semiconductor device according to claim 1,
wherein an average Al composition percentage of the first intermediate layer is higher than or equal to an average Al composition percentage of the second intermediate layer, and
an average Al composition percentage of the buffer layer is higher than the average Al composition percentage of the first intermediate layer.

6. The semiconductor device according to claim 1,
Wherein an average Al composition percentage of the first intermediate layer is at least 5% and at most 10%.

7. The semiconductor device according to claim 1,
wherein a difference between an average Al composition percentage of the second intermediate layer and an average Al composition percentage of the first intermediate layer is at most 5%.

8. The semiconductor device according to claim 1,
wherein a dangling bond at an upper surface of the buffer layer terminates with SiHₓ, where x is 0, 1, 2, or 3.

9. The semiconductor device according to claim 1,
wherein a dangling bond at an upper surface of the first intermediate layer terminates with SiH_{y}, where y is 0, 1, 2, or 3.

10. A method for manufacturing a semiconductor device comprising:
a first process of forming, above a substrate, a buffer layer consisting essentially of a group III nitride semiconductor;
a second process of forming, above the buffer layer, an intermediate layer consisting essentially of a group III nitride semiconductor having a band gap smaller than a band gap of the group III nitride semiconductor in the buffer layer;
a third process of forming, above the intermediate layer, an electron transport layer consisting essentially of a group III nitride semiconductor having a band gap smaller than the band gap of the group III nitride semiconductor in the intermediate layer;
a fourth process of forming, above the electron transport layer, an electron supply layer consisting essentially of a group III nitride semiconductor having a band gap greater than the band gap of the group III nitride semiconductor in the electron transport layer;
a fifth process of forming a source electrode and a drain electrode above the electron supply layer, the source electrode and the drain electrode being spaced apart from each other; and
a sixth process of forming a gate electrode above the electron supply layer, the gate electrode being spaced apart from each of the source electrode and the drain electrode,
wherein the second process includes:
a seventh process of forming a first intermediate layer above the buffer layer; and
an eighth process of forming a second intermediate layer above the first intermediate layer,
a value obtained by dividing a supply molar amount of a nitrogenous material in the eighth process by a supply molar amount of a group III material in the eighth process is at least 5000 and at most 20000, and
a substrate temperature in the eighth process is higher than or equal to a substrate temperature in the seventh process.

11. The method according to claim 10,
wherein the substrate temperature in the eighth process is at least 1100° C. and at most 1250° C.

12. The method according to claim 10,
wherein the second process includes, between the seventh process and the eighth process, a ninth process of stopping supply of a group III material gas.

13. The method according to claim 12,
wherein duration of the ninth process is at least one minute and at most five minutes.

14. The method according to claim 12,
wherein an SiH₄ gas is supplied in the ninth process.

15. The semiconductor device according to claim 2,
wherein an average Al composition percentage of the first intermediate layer is higher than or equal to an average Al composition percentage of the second intermediate layer, and
an average Al composition percentage of the buffer layer is higher than the average Al composition percentage of the first intermediate layer.

16. The semiconductor device according to claim 3,
wherein an average Al composition percentage of the first intermediate layer is higher than or equal to an average Al composition percentage of the second intermediate layer, and
an average Al composition percentage of the buffer layer is higher than the average Al composition percentage of the first intermediate layer.

17. The semiconductor device according to claim 2,
wherein an average Al composition percentage of the first intermediate layer is at least 5% and at most 10%.

18. The semiconductor device according to claim 3,
wherein an average Al composition percentage of the first intermediate layer is at least 5% and at most 10%.

19. The semiconductor device according to claim 2,
wherein a difference between an average Al composition percentage of the second intermediate layer and an average Al composition percentage of the first intermediate layer is at most 5%.

20. The semiconductor device according to claim 3,
wherein a difference between an average Al composition percentage of the second intermediate layer and an average Al composition percentage of the first intermediate layer is at most 5%.
